(19) United States
(12) Patent Application Publication
(10) Pub. No.: US 2020/0373149 A1
(43) Pub. Date: Nov. 26, 2020

(54) IN-SITU ATOMIC LAYER DEPOSITION PROCESS

(71) Applicant: Applied Materials, Inc., Santa Clara, CA (US)

(72) Inventors: Sang Wook PARK, Mountain View, CA (US); Xiaorui CUI, San Jose, CA (US); Sunil SRINIVASAN, San Jose, CA (US); Rajinder DHINDSA, Pleasanton, CA (US); Zhonghua YAO, Santa Clara, CA (US); Lin YU, San Jose, CA (US); Olivier LUERE, Sunnyvale, CA (US); Jonathan Sungehul KIM, Danville, CA (US)

(21) Appl. No.: 16/831,217

(22) Filed: Mar. 26, 2020

Related U.S. Application Data
(60) Provisional application No. 62/852,023, filed on May 23, 2019.

(51) Int. Cl. H01L 21/02; H01L 21/311

(52) U.S. Cl. CPC H01L 21/0228; H01L 21/31138; H01L 21/02301; H01L 21/0217; H01L 21/02211; H01L 21/02164

(57) ABSTRACT

Embodiments of the present disclosure provide methods and apparatus for forming a desired material layer on a substrate between, during, prior to or after a patterning process. In one embodiment, a method for forming a material layer on the substrate includes pulsing a first gas precursor comprising an organic silicon compound onto a surface of the substrate. The method also includes disposing a first element from the first gas precursor onto the surface of the substrate. The method further includes maintaining a substrate temperature less than about 110 degrees Celsius while disposing the first element. A second gas precursor is pulsed onto the surface of the substrate. Additionally, the method includes disposing a second element from the second gas precursor to the first element on the surface of the substrate.

### BACKGROUND

### Field

Examples of the present disclosure generally relate to a deposition process. Particularly, embodiments of the present disclosure provide methods for forming a material layer on a substrate using an in-situ atomic layer deposition process in an etching chamber.

### Description of the Related Art

In the manufacture of integrated circuits (IC), or chips, patterns representing different layers of the chip are created by a chip designer. A series of reusable masks, or photomasks, are created from these patterns in order to transfer the design of each chip layer onto a semiconductor substrate during the manufacturing process. Mask pattern generation systems use precision lasers or electron beams to image the design of each layer of the chip onto a respective mask. The masks are then used much like photographic negatives to transfer the circuit patterns for each layer onto a semiconductor substrate. These layers are built up using a sequence of processes and translate into the tiny transistors and electrical circuits that include each completed chip. Thus, any defects in the mask may be transferred to the chip, potentially adversely affecting performance. Defects that are severe enough may render the mask completely useless. Typically, a set of 15 to 100 masks is used to construct a chip and can be used repeatedly.

With the shrinking of critical dimensions (CD), present optical lithography is approaching a technological limit at the 45 nanometer (nm) technology node. Next generation lithography (NGL) is expected to replace the conventional optical lithography method, for example, in the 20 nm technology node and beyond. The images of the patterned mask are projected through the high-precision optical system onto the substrate surface, which is coated with a layer of photoresist. The patterns are then formed on the substrate surface after complex chemical reactions and follow-on manufacturing steps, such as development, post-exposure bake and wet or dry etching.

Multiple patterning technique is a technology developed for photolithography to enhance the feature density and accuracy. This technique is commonly used for patterns in the same layer which look different or have incompatible densities or pitches. Furthermore, between each patterning process, additional layers or structures may be formed, added or replenished in order to enable the next patterning process. Furthermore, as feature sizes have become smaller, the demand for higher aspect ratios, defined as the ratio between the depth of the feature and the width of the feature, has steadily increased to 20:1 and even greater. Developing etch processes and deposition processes that are capable of reliably forming features with such high aspect ratios or deposition material layers into such high aspect ratio features presents a significant challenge.

Therefore, there is a need for an apparatus for performing a patterning process, as well as a deposition process, with a desired material for features having high aspect ratios or other desired profiles.

### SUMMARY

Embodiments of the present disclosure provide methods and apparatus for forming a desired material layer on a substrate. In one embodiment, a method for forming a material layer on a substrate includes pulsing a first gas precursor including an organic silicon compound onto a surface of a substrate. The method includes disposing a first element from the first gas precursor onto the surface of the substrate. The method further includes maintaining a substrate temperature less than about 110 degrees Celsius while disposing the first element. Additionally, the method includes pulsing a second gas precursor onto the surface of the substrate. The method includes disposing a second element from the second gas precursor to the first element on the surface of the substrate.

In another embodiment, a method for forming a material layer on a substrate includes pulsing a first gas precursor including an organic silicon compound including a first element to a substrate disposed in an etching processing chamber. The method includes pulsing a second gas precursor including a second element to the substrate disposed in the etching processing chamber. Further, the method includes forming a material layer on a surface of the substrate in the etching processing chamber. The material layer includes the first and the second elements.

In yet another embodiment, a method for forming a material layer on a substrate includes sequentially pulsing a first and a second gas precursor to a surface of a substrate disposed in an etching process chamber. The first gas precursor includes an organic silicon compound. A substrate temperature is maintained at less than 110 degrees Celsius. The method includes selectively forming a material layer on the surface of the substrate.

### BRIEF DESCRIPTION OF THE DRAWINGS

So that the manner in which the above recited features of the present disclosure are attained and can be understood in detail, a more particular description of the disclosure, briefly summarized above, may be had by reference to the embodiments thereof which are illustrated in the appended drawings.

FIG. 1 is a schematic cross-sectional view of a processing chamber configured to perform a patterning process according to one or more embodiments of the disclosure;

FIG. 2 is a flowchart of a method for performing a deposition process, according to one or more embodiments of the present disclosure; and

FIGS. 3A-3E illustrate cross sectional views of a substrate during the deposition process of FIG. 2.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this disclosure and are therefore not to be considered limiting of its scope, for the disclosure may admit to other equally effective embodiments.

### DETAILED DESCRIPTION

Methods for forming a material layer on or in nanostructures with desired small dimensions are provided. The methods utilize an atomic layer deposition process at relatively low temperature, such as less than 110 degrees Celsius, in a processing chamber, such as an etching chamber. By a proper selection of a precursor as well as controlled process parameters, a material layer may be formed on a substrate or filled in a feature with high aspect ratios, such as greater than 20:1, formed on a substrate. The material layer may also be formed under a process temperature less than 110 degrees Celsius, so as to enable the deposition process to be formed in an etching processing chamber, which has a substrate support assembly operated under a room temperature, such as less than 110 degrees Celsius.

The term “substrate” as used herein refers to a layer of material that serves as a basis for subsequent processing operations and includes a surface to be cleaned. For example, the substrate can include one or more material containing silicon containing materials, group IV or group III-V containing compounds, such as Si, polysilicon, amorphous silicon, Ge, SiGe, GaAs, InP, InAs, GaAs, GaP, InGaAs, InGaAsP, GaSb, InSb and the like, or combinations thereof. Furthermore, the substrate can also include dielectric materials such as silicon dioxide, organosilicates, and carbon doped silicon oxides. The substrate may also include one or more conductive metals, such as nickel, titanium, platinum, molybdenum, rhenium, osmium, chromium, iron, aluminum, copper, tungsten, or combinations thereof. Further, the substrate can include any other materials such as metal nitrides, metal oxides and metal alloys, depending on the application. In one or more embodiments, the substrate can form a contact structure, a metal silicide layer, or a gate structure including a gate dielectric layer and a gate electrode layer to facilitate connecting with an interconnect feature, such as a plug, via, contact, line, and wire, subsequently formed thereon, or suitable structures utilized in semiconductor devices.

Moreover, the substrate is not limited to any particular size or shape. The substrate can be a round wafer having a 200 mm diameter, a 300 mm diameter, a 450 mm diameter or other diameters. The substrate can also be any polygonal, square, rectangular, curved or otherwise non-circular workpiece, such as a polygonal glass, plastic substrate used in the fabrication of flat panel displays.

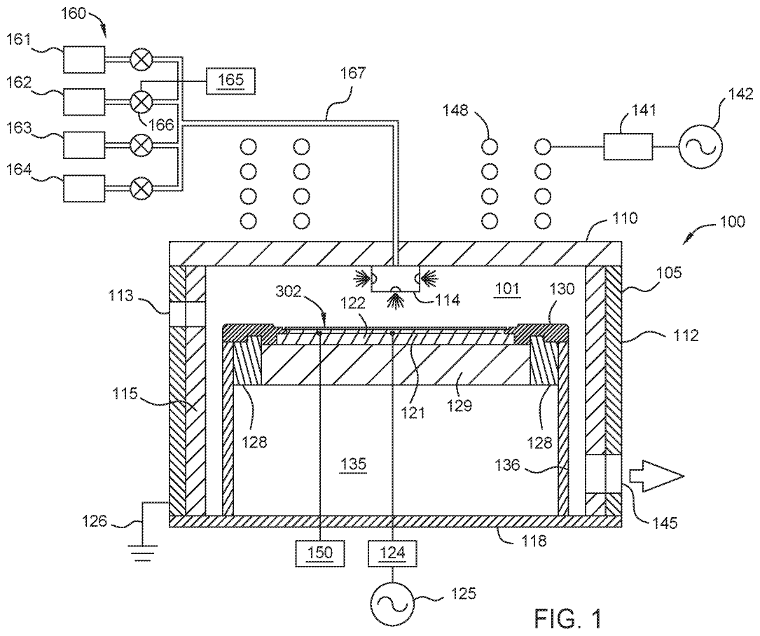

FIG. 1 is a simplified cutaway view for an exemplary plasma processing chamber 100 suitable for patterning a material layer as well as forming a material layer disposed on a substrate 302 in the plasma processing chamber 100. The exemplary plasma processing chamber 100 is suitable for performing a deposition process. One example of the plasma processing chamber 100 that may be adapted to benefit from the disclosure is an CENTRIS® Sym3™ etching processing chamber, available from Applied Materials, Inc., located in Santa Clara, Calif. It is contemplated that other process chambers, including those from other manufactures, may be adapted to practice embodiments of the disclosure.

The plasma processing chamber 100 includes a chamber body 105 having a chamber volume 101 defined therein. The chamber body 105 has sidewalls 112 and a bottom 118 which are coupled to ground 126. The sidewalls 112 have a liner 115 to protect the sidewalls 112 and extend the time between maintenance cycles of the plasma processing chamber 100. The dimensions of the chamber body 105 and related components of the plasma processing chamber 100 are not limited and may be are proportionally larger than the size of the substrate 302 to be processed therein. Examples of substrate sizes include 200 mm diameter, 250 mm diameter, 300 mm diameter and 450 mm diameter, among others.

The chamber body 105 supports a chamber lid assembly 110 to enclose the chamber volume 101. The chamber body 105 may be fabricated from aluminum or other suitable materials. A substrate access port 113 is formed through the sidewall 112 of the chamber body 105, facilitating the transfer of the substrate 302 into and out of the plasma processing chamber 100. The substrate access port 113 may be coupled to a transfer chamber and/or other chambers of a substrate processing system (not shown).

A pumping port 145 is formed through the sidewall 112 of the chamber body 105 and connected to the chamber volume 101. A pumping device (not shown) is coupled through the pumping port 145 to the chamber volume 101 to evacuate and control the pressure therein. The pumping device may include one or more pumps and throttle valves.

A gas panel 160 is coupled by a gas line 167 to the chamber body 105 to supply process gases into the chamber volume 101. The gas panel 160 may include one or more process gas sources 161, 162, 163, 164 and may additionally include inert gases, non-reactive gases, and reactive gases, if desired. Examples of process gases that may be provided by the gas panel 160 include, but are not limited to, hydrocarbon containing gas including methane (CH₄), silicon containing gas, such as sulfur hexafluoride (SF₆), silicon chloride (SiCl₄), or organic silicon containing gas, such as bis(diethylamido)Silane (BDEAS), tris(dimethylamino)silane (TDMAS), bis(tertiary-butylamino)silane (BTBAS), and the like, carbon tetrafluoride (CF₄), hydrogen bromide (HBr), hydrocarbon containing gas, argon gas (Ar), chlorine (Cl₂), nitrogen (N₂), helium (He) and oxygen gas (O₂). Additionally, process gasses may include nitrogen, chlorine, fluorine, oxygen and hydrogen containing gases such as BCl₃, C₂F₄, C₄F₈, C₄F₆, CHF₃, CH₂F₂, CH₃F, NF₃, NH₃, CO₂, SO₂, CO, N₂, NO₂, N₂O and H₂ among others.

Valves 166 control the flow of the process gases from the sources 161, 162, 163, 164 from the gas panel 160 and are managed by a controller 165. The flow of the gases supplied to the chamber body 105 from the gas panel 160 may include combinations of the gases.

The chamber lid assembly 110 may include a nozzle 114. The nozzle 114 has one or more ports for introducing the process gases from the sources 161, 162, 164, 163 of the gas panel 160 into the chamber volume 101. After the process gases are introduced into the plasma processing chamber 100, the gases are energized to form plasma. An antenna 148, such as one or more inductor coils, may be provided adjacent to the plasma processing chamber 100. An antenna power supply 142 may power the antenna 148 through a match circuit 141 to inductively couple energy, such as RF energy, to the process gas to maintain a plasma formed from the process gas in the chamber volume 101 of the plasma processing chamber 100. Alternatively, or in addition to the antenna power supply 142, process electrodes below the substrate 302 and/or above the substrate 302 may be used to capacitively couple RF power to the process gases to maintain the plasma within the chamber volume 101. The operation of the antenna power supply 142 may be controlled by a controller, such as controller 165, that also controls the operation of other components in the plasma processing chamber 100.

A substrate support pedestal 135 is disposed in the chamber volume 101 to support the substrate 302 during processing. The substrate support pedestal 135 may include an electrostatic chuck (ESC) 122 for holding the substrate 302 during processing. The ESC 122 uses the electrostatic attraction to hold the substrate 302 to the substrate support pedestal 135. The ESC 122 is powered by an RF power supply 125 integrated with a match circuit 124. The ESC 122 includes an electrode 121 embedded within a dielectric body. The electrode 121 is coupled to the RF power supply 125 and provides a bias which attracts plasma ions, formed by the process gases in the chamber volume 101, to the ESC 122 and substrate 302 positioned thereon. The RF power supply 125 may cycle on and off, or pulse, during processing of the substrate 302. The ESC 122 has an isolator 128 for the purpose of making the sidewall of the ESC 122 less attractive to the plasma to prolong the maintenance life cycle of the ESC 122. Additionally, the substrate support pedestal 135 may have a cathode liner 136 to protect the sidewalls of the substrate support pedestal 135 from the plasma gases and to extend the time between maintenance of the plasma processing chamber 100.

Furthermore, the electrode 121 is coupled to a power source 150. The power source 150 provides a chucking voltage of about 200 volts to about 2000 volts to the electrode 121. The power source 150 may also include a system controller for controlling the operation of the electrode 121 by directing a DC current to the electrode 121 for chucking and de-chucking the substrate 302.

The ESC 122 may include heaters disposed therein and connected to a power source (not shown), for heating the substrate, while a cooling base 129 supporting the ESC 122 may include conduits for circulating a heat transfer fluid to maintain a temperature of the ESC 122 and substrate 302 disposed thereon. The ESC 122 is configured to perform in the temperature range desired by the thermal budget of the device being fabricated on the substrate 302. For example, the ESC 122 may be configured to maintain the substrate 302 at a temperature of about minus about 25 degrees Celsius to about 150 degrees Celsius for certain embodiments.

The cooling base 129 is provided to assist in controlling the temperature of the substrate 302. To mitigate process drift and time, the temperature of the substrate 302 may be maintained substantially constant by the cooling base 129 throughout the time the substrate 302 is in the cleaning chamber. In one embodiment, the temperature of the substrate 302 is maintained throughout subsequent cleaning processes at about 30 to 120 degrees Celsius.

A cover ring 130 is disposed on the ESC 122 and along the periphery of the substrate support pedestal 135. The cover ring 130 is configured to confine etching gases to a desired portion of the exposed top surface of the substrate 302, while shielding the top surface of the substrate support pedestal 135 from the plasma environment inside the plasma processing chamber 100. Lift pins (not shown) are selectively moved through the substrate support pedestal 135 to lift the substrate 302 above the substrate support pedestal 135 to facilitate access to the substrate 302 by a transfer robot (not shown) or other suitable transfer mechanism.

The controller 165 may be utilized to control the process sequence, regulating the gas flows from the gas panel 160 into the plasma processing chamber 100 and other process parameters. Software routines, when executed by the CPU, transform the CPU into a specific purpose computer (controller) that controls the plasma processing chamber 100 such that the processes are performed in accordance with the present disclosure. The software routines may also be stored and/or executed by a second controller (not shown) that is collocated with the plasma processing chamber 100.

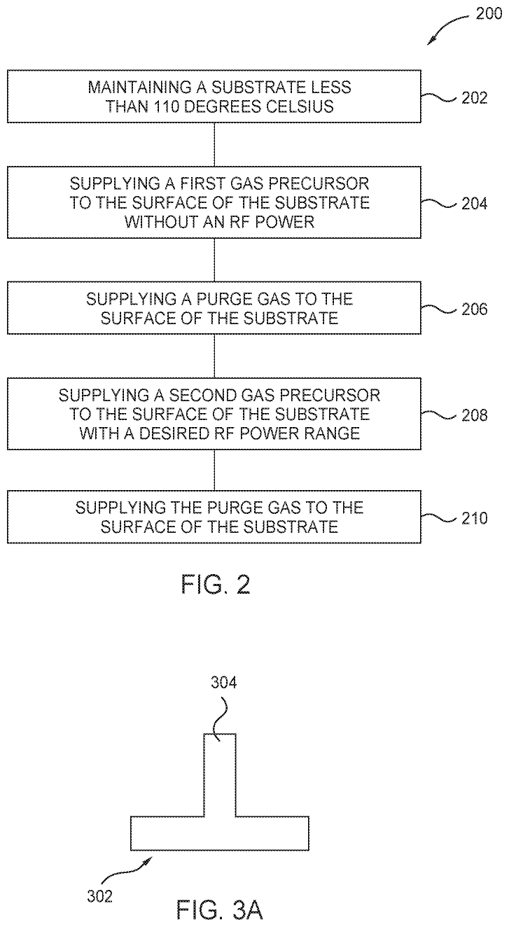

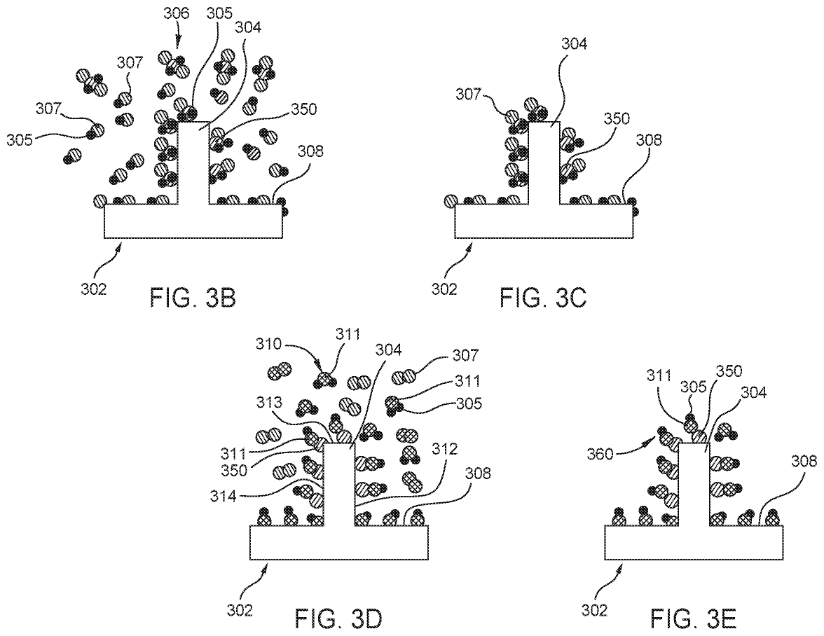

FIG. 2 is a flow diagram of one example of a method 200 for in-situ deposition process for depositing a material layer on a substrate in an etching or patterning processing chamber. The material layer may be later utilized to serve as a mask layer, a liner layer, a barrier layer, a spacer layer, a filling layer or a passivation layer to further alter dimensions or profiles of the features on the substrate for further feature transfer to the underlying layers disposed under the material layer. FIGS. 3A-3E are cross-sectional views of a portion of a substrate 302 with a structure 304 formed thereon corresponding to various stages of the method 200.

The method 200 may be utilized to deposit material layers onto structures 304 formed on the substrate 302 with different material requirements so as to form different structures. Suitable materials for the underlying layers (not shown) may include an interlayer dielectric layer, contact dielectric layer, a gate electrode layer, a gate dielectric layer, a STI insulating layer, inter-metal layer (IML), or any suitable layers. The structure 304 may be a material such as crystalline silicon (e.g., Si<100> or Si<111>), silicon oxide, strained silicon, silicon germanium, germanium, doped or undoped polysilicon, doped or undoped silicon wafers and patterned or non-patterned wafers silicon on insulator (SOI), carbon doped silicon oxides, silicon nitride, doped silicon, germanium, gallium arsenide, glass, or sapphire. The structure 304 may have various dimensions, such as 200 mm, 300 mm, 450 mm or other diameter, as well as, being a rectangular or square panel. Unless otherwise noted, examples described herein are conducted on substrates with a 200 mm diameter, a 300 mm diameter, or a 450 mm diameter substrate.

Alternatively, the method 200 may be beneficially utilized to form materials on suitable types of structures as needed.

The method 200 begins at operation 202 by providing the substrate 302 having the structure 304 formed thereon, as shown in FIG. 3A. The substrate 302 is placed in a processing chamber, such as the plasma processing chamber 100 depicted in FIG. 1 to perform a deposition process. In one example, the plasma processing chamber 100 is an etching chamber or a patterning chamber that allows the substrate 302 to be disposed therein to perform a deposition process. The structure 304 includes patterned features formed in a desired distance away from each other. In one embodiment, the structure 304 may be fabricated from a dielectric layer or a photoresist layer utilized to form a layer in a semiconductor device. Suitable examples of the dielectric layer include carbon-containing silicon oxides (SiOC), polymer materials, such as polyamides, SOG, USG, silicon oxide, silicon nitride, silicon oxynitride, silicon carbide, silicon oxycarbide, or the like.

In the example depicted in FIGS. 3A-3E, the structure 304 includes a silicon containing material or a dielectric layer. Suitable examples for the silicon containing material include crystalline silicon, silicon oxide, strained silicon, silicon germanium, germanium, doped or undoped polysilicon and other doped or undoped silicon containing materials as needed. Suitable examples of the dielectric layer may be a silicon oxide, silicon nitride, silicon oxynitride (SiON), silicon oxycarbide (SiOC), or amorphous carbon materials as needed.

At operation 204, a first gas precursor 306 is supplied into the plasma processing chamber 100 into the surface of the substrate 302, as shown in FIG. 3B. In one example, the first gas precursor 306 includes a first element, such as silicon element 350, which may have high absorption capability to the substrate 302 as well as to the structure 304. For example, when the substrate 302 and/or the structure 304 includes atoms or elements that are the same as or similar to the atoms or elements in the first gas precursor 306, the atoms or elements from the first gas precursor 306 may be successfully adhered, absorbed or attached to the atoms or elements from the substrate 302 and/or from the structure 304 to enhance the attachment and bonding therebetween. For example, when the substrate 302 and/or the structure 304 include silicon elements 350, the first element from the first gas precursor 306 as selected also includes a silicon element so that the silicon element from the first gas precursor 306 may be successfully adhered, absorbed or attached to the silicon elements from the substrate 302 and/or the structure 304. Suitable examples of the first gas precursor 306 are a silicon containing gas, such as an organic silicon compounds. The organic silicon compound is desired to be maintained in as liquid state at room temperature, such as between −10 degrees Celsius and about 50 degrees Celsius. Furthermore, the organic silicon compound is also maintained at a relatively stable status when placing at the room temperature environment. In one example, the organic silicon compound includes aminosilane precursors. The amino ligands from the aminosilane precursors are configured to be easily dissociated from silicon and then dangling bonds of silicon can form chemisorption with the surface. At the same time, the other ligands are preventing further reactions with other precursors and thus self-limiting characteristic could be achieved.

Suitable examples of the organic silicon compounds include bis(diethylAmido)silane (BDEAS), tris(dimethylamino)silane (TDMAS), bis(tertiary-butylamino)silane (BTBAS) and trisilylamine (TSA). In one particular example, the organic silicon compound selected for the first gas precursor 306 is bis(diethylAmido)silane (BDEAS) or bis(tertiary-butylamino)silane (BTBAS).

The silicon elements 350 is served as the first element from the first gas precursor 306 to be absorbed onto the surfaces of the substrate 302 and/or the structure 304.

The first gas precursor 306 is pulsed into the plasma processing chamber 100 to perform an atomic layer deposition (ALD) process. For example, each pulse of an ALD process enables the growth and deposition of a monolayer of a material layer. The atomic layer deposition (ALD) process is a chemical vapor deposition (CVD) process with self-terminating/limiting growth. The ALD process yields a thickness of only a few angstroms or in a monolayer level. The ALD process is controlled by distribution of a chemical reaction into two separate half reactions which are repeated in cycles, which are included in operations 204 and 208 in method 200 described herein. The thickness of the material layer formed by the ALD process depends on the number of reaction cycles. The first gas precursor 306 pulse lasts for a predetermined time interval. The term pulse as used herein refers to a dose of material injected into the process chamber.

The first reaction from the first gas precursor 306 at operation 204 provides a first atomic layer of molecular layer (e.g., sourced from the first element from the first gas precursor) that is absorbed on the substrate and a second reaction of a second element from a second gas precursor, which will be described later at operation 208, provides a second atomic layer of molecular layer that is absorbed on the first atomic layer. In the example depicted in FIG. 3B, the first gas precursor 306 (e.g., bis(diethylAmido)silane (BDEAS) precursor) includes multiple elements, such as silicon and hydrogen, as well as ligands, such as N—(C₂H₅)₂ ligands. Below please find the chemical structure of the bis(diethylAmido)silane (BDEAS) precursor used for the first gas precursor 306 as one example.

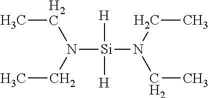

When the first gas precursor 306 is supplied to the substrate, the silicon elements 350 tend to be absorbed and adhered onto the top surface and sidewalls of the structure 304 as well as an upper surface 308 of the substrate 302, which also have silicon elements. Other elements, such as hydrogen elements 305 and ligands 307 (e.g., N—(C₂H₅)₂ ligands), which do not share the same elements from the substrate 302 and/or the structure 304, are then dangling adjacent to the structure 304, with loose bonds or no bonds, to the structure 304 and/or the substrate 302, as shown in FIG. 3B. Thus, a selective deposition process is also obtained by forming the first monolayer on certain surface of the substrate that provides similar or the same elements from the first element from the first gas precursor 306.

Several process parameters are also regulated during pulsing of the first gas precursor 306. In one embodiment, the process pressure is controlled at between about 1 mTorr and about 100 mTorr. The processing temperature is maintained at less than about 110 degrees Celsius, such as between about −10 degrees Celsius and about 110 degrees Celsius, such as between about 20 degrees Celsius and about 90 degrees Celsius. While supplying the first gas precursor 306, the RF powers, such as RF bias power or RF source power, may be eliminated as needed. It is believed that a plasma free environment may allow the elements to gently and slowly fall on the substrate surface, thus enhancing conformal deposition of the material layer on the substrate surface. In some embodiment, the RF source or bias power may be, alternatively or simultaneously, applied as needed to generate a plasma while supplying the first gas precursor 306 as needed. The first gas precursor 306 may be supplied at between about 5 sccm and about 150 sccm. Each pulse of the first precursor gas may deposit the first monolayer of a material layer 360 (as shown in FIG. 3E) having a thickness between about 3 Å and about 5 Å.

At operation 206, a purge gas is then supplied to the plasma processing chamber 100 to purge out the atoms and/or elements (e.g., the hydrogen elements 305 and the ligands 307 (e.g., N—(C₂H₅)₂ ligands)) not attached to the substrate 302 and/or the structure 304, as shown in FIG. 3C. Suitable examples of the purge gas include an insert gas, such as Ar or He, a nitrogen containing gas, or other suitable gases.

Several process parameters are also regulated during pulsing of the purge gas mixture. In one embodiment, the process pressure is controlled at between about 1 mTorr and about 100 mTorr. The processing temperature is maintained at less than about 110 degrees Celsius, such as between about −10 degrees Celsius and about 110 degrees Celsius, such as between about 20 degrees Celsius and about 100 degrees Celsius. The RF source power may be controlled at between about 100 watts and about 1200 watts, such as between about 500 watts and about 1000 watts. The RF bias power may be controlled at between about 10 watts and about 200 watts, such as between about 50 watts and about 100 watts. The purge gas may be supplied at between about 5 sccm and about 150 sccm.

At operation 208, a second gas precursor 310 is supplied into the plasma processing chamber 100 into the surface of the substrate 302, as shown in FIG. 3D. In one example, the second gas precursor 310 includes a second element which can react with the first element, such as the silicon element 350, on the substrate 302 and/or the structure 304 provided from the first gas precursor 306. The second element as pulsed reacts and bonds with the first element, such as the silicon element 350 on the surfaces 313, 314 and a sidewall 312 of the substrate 302 and/or the structure 304. In the example disposed in FIG. 3D, the second gas precursor 310 includes an oxygen or a nitrogen containing gas, providing an oxygen or a nitrogen element 311. It is noted that other suitable second gas precursor 310 that is capable of providing elements or atoms to react with the elements from the first gas precursor may also be utilized as needed. The oxygen or nitrogen element 311 reacts with the silicon element 350. The oxygen or nitrogen element 311 is then absorbed by the silicon element 350 on the substrate 302 and/or the structure 304, forming a material layer 360 (as shown in FIG. 3E) on the surfaces and the sidewall of the substrate 302 and/or the structure 304. In the example wherein the second element is an oxygen element 311, the material layer 360 as formed on the substrate 302 is a silicon oxide layer. In another example wherein the second element is a nitrogen element 311, the material layer 360 as formed on the substrate 302 is a silicon nitride layer.

Suitable examples of the oxygen containing gas include O₂, CO₂, H₂O and the like. Suitable examples of the nitrogen containing gas include N₂, NO₂, N₂O, NH₃, and the like. In one example, the oxygen containing gas is O₂ and the nitrogen containing gas is NH₃ or N₂.

Based on different process requirements, process parameters may be controlled differently at operation 208. In the example wherein the material layer 360 is desired to be formed conformally across the substrate 302 and/or the structure 304, as shown in FIGS. 3D and 3E, a suitable range of RF bias power and/or source power may be applied to activate the elements as well as provide directionality of the elements or atoms toward the surfaces and the sidewall of the substrate 302 and/or the structure 304. With the assistance from the RF bias power and/or the RF source power, the elements or atoms from the second gas precursor 310 may stay on the top surface of the structure 304 as well as accelerated toward the sidewall of the structure 304 and the upper surface 308 of the substrate 302.

Several process parameters are also regulated during pulsing of the second gas precursor 310. In one embodiment, the process pressure is controlled at between about 1 mTorr and about 100 mTorr. The processing temperature is maintained at less than about 110 degrees Celsius, such as between about −10 degrees Celsius and about 110 degrees Celsius, such as between about 20 degrees Celsius and about 100 degrees Celsius. The RF source power may be controlled at between about 100 watts and about 2500 watts, such as about 500 watts and about 1000 watts. The RF bias power may be optionally supplied while supplying the second gas precursor. It is believed that the RF source and bias powers as applied may assist activating the oxygen or nitrogen elements 311 as well as the silicon elements 350 from the substrate 302 in an activated/excited state, so as to enhance the absorption of the oxygen or nitrogen elements 311 to the silicon elements 350. Each pulse of the second precursor gas may deposit the first monolayer of the material layer 360 having a thickness between about 3 Å and about 15 Å.

At operation 210, a purge gas is then supplied to the plasma processing chamber 100 to purge out the atoms and/or elements not attached to the substrate 302 and/or the structure 304, as shown in FIG. 3E, similar to the purge gas supply at operation 206. Suitable examples of the purge gas include an insert gas, such as Ar or He, a nitrogen containing gas, or other suitable gases.

Several process parameters are also regulated during pulsing of the purge gas mixture. In one embodiment, the process pressure is controlled at between about 1 mTorr and about 100 mTorr. The processing temperature is maintained at less than about 110 degrees Celsius, such as between about −10 degrees Celsius and about 120 degrees Celsius, such as between about 20 degrees Celsius and about 100 degrees Celsius. The RF source power may be controlled at between about 100 watts and about 2500 watts, such as between about 500 watts and about 1000 watts. The RF bias power may be controlled at between about 10 watts and about 500 watts, such as between about 50 watts and about 100 watts. The purge gas may be supplied at between about 5 sccm and about 150 sccm.

As such, the ordered structure of the monolayers composed from the first elements and the second elements from the operations 204 and 208 is then formed on the structured material layer 360 at desired locations of the substrate 302. The first monolayer from the first gas precursor 306 at operation 204 is absorbed onto the desired locations of the substrate 302 and the structure 304 by a chemical reaction that allows the atoms from the first monolayer to be securely adhered on the atoms the substrate 302 and the structure 304. The subsequently formed second monolayer from the second gas precursor 310 at operation 208 is then selectively formed at desired locations of the substrate 302 and the structure 304, thus enabling a deposition of an ALD process at a low temperature, such as less than 110 degrees Celsius, in a processing chamber, such as an etching chamber.

Between each pulse of the first gas precursor 306 or the second gas precursor 310 at operations 204 and 208, the purge gas at operation 206 may be pulsed into the processing chamber in between each or multiple pulses of the first and/or second gas precursors 306, 310 to remove the impurities or residual precursor gas mixture which is unreacted/non-absorbed by the substrate surface (e.g., unreacted impurities from the reactant gas mixture or others) so they can be pumped out of the processing chamber.

In the example wherein the second gas precursor 310 is an oxygen containing gas, the resultant material layer 360 is a silicon oxide layer. In the example wherein the second gas precursor 310 is a nitrogen containing gas, the resultant material layer 360 is a silicon nitride layer.

It is noted that additional cycles starting from the pulsing of the first gas precursor 306 at operation 204, the purge gas supply at operation 206 and the second gas precursor 310 at operation 208 can then be repeatedly performed until a desired thickness of the material layer 360 is obtained. When a subsequent cycle of pulsing the first gas precursor 306 starts, the process pressure and other process parameters may be regulated to the predetermined level to assist depositing a subsequent monolayer of the material layer 360.

Thus, deposition methods for forming a material layer on a structure of a substrate are provided. The deposition methods utilize an ALD-like deposition process performed at a temperature less than 110 degrees Celsius to form the material layer in an etching processing chamber so that an etching process may immediately follow after the deposition process of the material layer as needed. Furthermore, the low temperature deposition process also enables the material layer to be formed in any substrate with suitable features, such as high aspect ratios greater than 20:1, which requires slow and conformal deposition profiles. Thus, process cycle time and manufacturing throughput may be improved and well managed.

While the foregoing is directed to embodiments of the present disclosure, other and further embodiments of the disclosure may be devised without departing from the basic scope thereof, and the scope thereof is determined by the claims that follow.

We claim:

1. A method for forming a material layer on a substrate, comprising:
pulsing a first gas precursor comprising an organic silicon compound onto a surface of a substrate;
disposing a first element from the first gas precursor onto the surface of the substrate;
maintaining a substrate temperature less than about 110 degrees Celsius while disposing the first element;
pulsing a second gas precursor onto the surface of the substrate; and
disposing a second element from the second gas precursor to the first element on the surface of the substrate.

2. The method of claim 1, wherein pulsing the first gas precursor further comprises:
pulsing the first gas precursor without generating a plasma from the first gas precursor.

3. The method of claim 1, wherein the first gas precursor is pulsed onto the surface of the substrate disposed in an etching processing chamber.

4. The method of claim 1, wherein the first gas precursor is pulsed to the surface of the substrate without applying a RF source power or a bias power.

5. The method of claim 4, wherein the substrate temperature is maintained between about −20 degrees Celsius and about 50 degrees Celsius while pulsing the first gas precursor.

6. The method of claim 1, wherein the organic silicon compound comprises aminosilane.

7. The method of claim 6, wherein the organic silicon compound is at least one of bis(DiEthylAmido)Silane (BDEAS) or tris(dimethylamino)silane (TDMAS), bis(tertiary-butylamino)silane (BTBAS).

8. The method of claim 1, wherein pulsing the second gas precursor further comprises:
applying a RF source power and a RF bias power while pulsing the second gas precursor.

9. The method of claim 1, wherein a purge gas is supplied between pulsing of the first and second gas precursors.

10. The method of claim 1, wherein the second gas precursor comprises a nitrogen or oxygen containing gas.

11. The method of claim 10, wherein the nitrogen or oxygen containing gas is N₂ or O₂.

12. The method of claim 1, further comprising:
forming a material layer conformally on a surface of a feature disposed on the substrate.

13. The method of claim 12, wherein the feature has an aspect ratio greater than 20:1.

14. The method of claim 12, wherein the material layer is formed from silicon oxide or silicon nitride.

15. The method of claim 1, further comprising:
selectively forming a material layer on a surface of a structure on a substrate.

16. A method for forming a material layer on a substrate comprising:
pulsing a first gas precursor, comprising an organic silicon compound comprising a first element, to a substrate disposed in an etching processing chamber;
pulsing a second gas precursor comprising a second element to the substrate disposed in the etching processing chamber; and
forming a material layer on a surface of the substrate in the etching processing chamber, wherein the material layer comprises the first and second elements.

17. The method of claim 16 further comprising:
maintaining a substrate temperature of less than 110 degrees Celsius.

18. The method of claim 16, wherein the first gas precursor is pulsed into the etching processing chamber without applying RF source power or bias power to the etching processing chamber.

19. The method of claim 16, wherein the second gas precursor is pulsed into the etching processing chamber while applying RF bias power or RF source power to the etching processing chamber.

20. A method for forming a material layer on a substrate comprising:
sequentially pulsing a first gas precursor and a second gas precursor to a surface of a substrate disposed in an etching process chamber, wherein the first gas precursor comprises an organic silicon compound;
maintaining a substrate temperature of less than 110 degrees Celsius; and
selectively forming a material layer on the surface of the substrate.
